(19) United States
(12) Patent Application Publication
(10) Pub. No.: US 2019/0074659 A1
(43) Pub. Date: Mar. 7, 2019

(54) METHOD FOR REDUCING SELF-MIXING INTERFERENCE EFFECT OF LASER SYSTEM

(71) Applicant: WUXI MILEWAVE PHOTONICS TECHNOLOGIES CO., LTD, Wuxi City, Jiangsu Province (CN)

(72) Inventors: Jintong ZHU, Wuxi City, Jiangsu Province (CN); Hua LIU, Wuxi City, Jiangsu Province (CN); Naiyou GU, Wuxi City, Jiangsu Province (CN)

(21) Appl. No.: 16/077,614

(22) PCT Filed: Sep. 11, 2017
(86) PCT No.: PCT/CN2017/101190

§ 371 Date: Aug. 13, 2018

(30) Foreign Application Priority Data
Sep. 12, 2016 (CN) 201610817138.X

(51) Int. Cl. H01S 5/0683; H01S 5/042; H01S 5/00

(52) U.S. Cl. CPC H01S 5/0683; H01S 5/0085; H01S 5/0427

(57) ABSTRACT

The present invention discloses a method for reducing a self-mixing interference effect of a laser system, comprising the following step: connecting a direct current (DC) bias circuit and a modulated signal generator to electrodes of a laser, respectively. The DC bias circuit is configured to drive the laser and provide carriers for pumping to the laser; a resonant cavity is provided in the laser, and is configured to convert the carriers for pumping into photons which are subjected to stimulated radiation to form stable laser output; the DC bias circuit and the modulated signal generator are injected into the laser; the modulated signal generator outputs a modulated signal; and the modulated signal matches a parasitic parameter of the laser so as to change the distribution state of the photons in the resonant cavity of the laser. The present invention spatially and temporally reduces power fluctuation of a laser within a short period of time caused by the self-mixing interference effect, ensures the stability of the whole laser system, and has the advantages of low cost, easy assembly and adjustment, and stable performance.

### TECHNICAL FIELD

The present invention relates to the technical field of laser s, and in particular, to a method for reducing a self-mixing interference effect of a laser system.

### RELATED ART

Laser plays a unique and crucial role in the fields such as industries, communications, medicines, scientific researches and social lives due to its characteristics such as high brightness, high coherence and high collimation. However, in some cases where high stability of a laser is required, because externally emitted laser light or laser light emitted from a laser window, a beam shaping element or other parts would be coupled into a resonant cavity of the laser to form a self-mixing interference effect, less coupling reflected light would cause an unstable performance of the laser. If the coupling reflected light is strong, the self-mixing interference effect causes damage to the resonant cavity of the laser, which directly affects the service life of the laser.

A single mode laser diode (for example, a DFB or VCSEL laser diode that employs adjustability of a diode in the aspect of an emission wavelength) would easily cause power instability of the output power within an extremely short period of time due to the utilization of high concentrations of carriers. Therefore, the concentration fluctuations of the carriers would affect the refractive index of an active area. If a resonator has a shorter length and further adopts a cleavage plane of low reflectivity, an oscillator of the laser would be easily affected by the external reflected light. Furthermore, fluctuations of the refractive index of the active area due to the fluctuations of carriers cause the original stable resonant cavity to be in an unstable state, or because the resonance effect of the laser is not stable and coupling of spontaneous emission to an oscillation mode is further increased, the whole process is repeatedly performed, thereby increasing the output instability of the laser, and thus failing to achieve highly sensitive inspection or application in the application process.

The invention patent (CN102195233A) represents a method for reducing a self-mixing interference effect by means of dynamic adjustment, and illustrates an electrically controllable power device for periodically changing positions and arrangement of optical elements relative to laser diodes, so as to periodically change the optical path length of the laser beams in a shell. The oscillation motion of the optical elements has an effect of time-averaging an etalon effect caused by back reflection of the laser beams in the shell and the self-mixing effect, thereby reducing the optical noise of a laser diode structure. The method can reduce instability of output light beams of a laser system caused by the self-mixing interference effect, but the implementation process is complicated. Because dynamic mobile elements exist in the system, system instability factors caused by the presence of the dynamic elements in the system would easily occur during the process, and a driving circuit configured to provide power to the dynamic elements in the process would also cause redundancy and indeterminacy of the system.

### SUMMARY OF THE INVENTION

The purpose of the present invention is to provide a method for reducing a self-mixing interference effect of a laser system with stable performance and less energy loss applicable to efficient and stable laser systems, in order to solve the problems in the prior art above by changing balance in a resonant cavity according to the relationships between photons and carriers in the resonant cavity so as to effectively control the instability of light beams output by the laser system caused by a self-mixing interference effect.

The purpose of the present invention is achieved by the following technical solution: a method for reducing a self-mixing interference effect of a laser system, comprising the following steps: S1: connecting a DC bias circuit and a modulated signal generator to electrodes of a laser, respectively, wherein the DC bias circuit is configured to drive the laser and provide carriers for pumping to the laser; a resonant cavity is provided in the laser, and is configured to convert the carriers for pumping into photons which are subjected to stimulated radiation to form stable laser output; the DC bias circuit and the modulated signal generator are injected into the laser; the modulated signal generator outputs a modulated signal; and the modulated signal matches a parasitic parameter of the laser so as to change the distribution state of the photons in the resonant cavity of the laser;

the relation equation of the carriers and the photons of the laser is as follows:

$$\frac{{dN}_{sch}}{dt} = \frac{{η}_{i} J}{{qW}_{sch 1}} - {N}_{sch} {\sum }_{z = 1}^{M} \frac{{υ}_{2}}{{τ}_{cap , 1}} - \frac{{N}_{sch} ( 1 - {\sum }_{z = 1}^{M} {υ}_{2} )}{{τ}_{nsch}} - \frac{{N}_{M}}{{τ}_{c}} \frac{{W}_{qw}}{{W}_{sch 2}}$$

$$\frac{{dN}_{1}}{dt} = {N}_{sch} \frac{{υ}_{1}}{{τ}_{cap , 1}} \frac{{W}_{sch 1}}{{W}_{qw}} - \frac{{N}_{1}}{{τ}_{c}} - \frac{{N}_{1}}{{τ}_{nqw}} - \frac{{N}_{1} - {N}_{2}}{{τ}_{c}} - {v}_{g} g ( {N}_{z} ) ( 1 - ɛ Γ S ) S$$

$$\frac{{dN}_{z}}{dt} = {N}_{sch} \frac{{υ}_{z}}{{τ}_{cap , z}} \frac{{W}_{sch 1}}{{W}_{qw}} + \frac{{N}_{z} - {N}_{z - 1}}{{τ}_{c}} - \frac{{N}_{z}}{{τ}_{e}} - \frac{{N}_{z}}{{τ}_{nqw}} - \frac{{N}_{z} - {N}_{z - 1}}{{τ}_{c}} - {v}_{g} g ( {N}_{z} ) ( 1 - ɛ Γ S ) S$$

$$\frac{{dN}_{M}}{dt} = {N}_{sch} \frac{{υ}_{M}}{{τ}_{cap , M}} \frac{{W}_{sch 1}}{{W}_{qw}} + \frac{{N}_{M} - {N}_{M - 1}}{{τ}_{c}} - \frac{{N}_{M}}{{τ}_{e}} - \frac{{N}_{M}}{{τ}_{nqw}} - {v}_{g} g ( {N}_{M} ) ( 1 - ɛ Γ S ) S$$

$$\frac{dS}{dt} = Γ {v}_{g} [ {\sum }_{z = 1}^{M} g ( {N}_{M} ) ] ( 1 - ɛ Γ S ) S - \frac{S}{{τ}_{p}} + \frac{β}{M} {\sum }_{z = 1}^{M} \frac{{N}_{z}}{{τ}_{n} ( {N}_{z} )}$$

S2: affecting the distribution state of balanced photons of the laser by injection of the carriers matching the resonant cavity of the laser, and then causing the photons in the state to encounter external reflected light or laser light reflected by a laser window or an optical element to form a self-mixing interference effect, so as to improve the stability of the laser light output by the laser.

Preferably, the parasitic parameter is a parasitic capacitance or a parasitic resistance; the DC bias circuit and the modulated signal generator are injected into the laser; the modulated signal, the parasitic capacitance, and the parasitic resistance constitute a resonance relationship which is embodied as a chirp effect in terms of optical output; resonant cavity laser output modes are increased, after a trace amount of returned light is applied to the laser, the influence of the self-mixing interference effect in multiple modes on the laser is less than that of equivalent self-mixing interference effect in a single mode or a few modes, and then the laser outputs stable laser beams.

Preferably, the laser is disposed along an optical axis (Z direction), the DC bias circuit and the modulated signal generator are spaced apart from the laser, and the laser is electrically connected to the DC bias circuit and the modulated signal generator.

Preferably, an optical element configured to guide the light beams and/or shape the laser beams is disposed behind the laser at an interval.

Preferably, the modulated signal generator may be a digital signal generator or an analog signal generator.

Preferably, the optical element is a diffractive optical element (DOE).

The advantages of the technical solution of the present invention are mainly embodied in: spatially and temporally reducing power fluctuation of a laser within a short period of time caused by the self-mixing interference effect, ensuring the stability of the whole laser system, and having capability of effectively reducing influence of the returned light on the stability of the laser, so as to effectively reduce the self-mixing interference effect and then reduce the stability of the laser. The laser system is simple and feasible, is applicable to efficient and stable laser systems, has the advantages of a simple structure, less energy loss in use, low cost, easy assembly and adjustment, and stable performance, and can be promoted and applied in industry.

### BRIEF DESCRIPTION OF THE DRAWINGS

With reference to the accompanying drawings, the contents disclosed in the present invention would be more understandable. A person of ordinary skill in the art would easily understand that the accompanying drawings are merely illustrative, and are not intended to limit the scope of protection of the present invention.

FIG. 1 is a schematic structural diagram of a laser system according to embodiment 1 of the utility model;

FIG. 2 is a schematic structural diagram of a laser system according to embodiment 2 of the utility model;

FIG. 3 is a schematic structural diagram of a DC bias circuit of the utility model;

FIG. 4 is a schematic diagram of an alternating current (AC) equivalent circuit of a multi-quantum well laser of the utility model;

FIG. 5 is a parameter corresponding diagram of an equivalent capacitance and an equivalent resistance of a multi-quantum well laser of the utility model;

FIG. 6 is a distribution diagram of the relative light intensity without using the laser of the utility model;

FIG. 7 is a distribution diagram of the relative light intensity of a laser in a spatial domain of the utility model;

FIG. 8 is a schematic structural diagram without using the laser of the utility model; and

FIG. 9 is a schematic structural diagram of a laser in a temporal domain of the utility model.

### DETAILED DESCRIPTION

The purpose, advantages and characteristics of the present invention are illustrated and explained by non-restrictive description of the following preferred embodiments. These embodiments are merely typical examples of applying the technical solution of the present invention. The technical solutions formed by equivalent replacements or equivalent transforms all fall within the scope of protection of the present invention.

A method for reducing a self-mixing interference effect of a laser system includes the following steps:

S1: connect a DC bias circuit and a modulated signal generator to electrodes of a laser, respectively, wherein the DC bias circuit is configured to drive the laser and provide carriers for pumping to the laser; a resonant cavity is provided in the laser, and is configured to convert the carriers for pumping into photons which are subjected to stimulated radiation to form stable laser output; the DC bias circuit and the modulated signal generator are injected into the laser; the modulated signal generator outputs a modulated signal; and the modulated signal matches a parasitic parameter of the laser so as to change the distribution state of the photons in the resonant cavity of the laser;

the relation equation of the carriers and the photons of the laser is as follows:

$$\frac{{dN}_{sch}}{dt} = \frac{{η}_{i} J}{{qW}_{sch 1}} - {N}_{sch} {\sum }_{z = 1}^{M} \frac{{υ}_{2}}{{τ}_{cap , 1}} - \frac{{N}_{sch} ( 1 - {\sum }_{z = 1}^{M} {υ}_{2} )}{{τ}_{nsch}} - \frac{{N}_{M}}{{τ}_{c}} \frac{{W}_{qw}}{{W}_{sch 2}}$$

$$\frac{{dN}_{1}}{dt} = {N}_{sch} \frac{{υ}_{1}}{{τ}_{cap , 1}} \frac{{W}_{sch 1}}{{W}_{qw}} - \frac{{N}_{1}}{{τ}_{c}} - \frac{{N}_{1}}{{τ}_{nqw}} - \frac{{N}_{1} - {N}_{2}}{{τ}_{c}} - {v}_{g} g ( {N}_{z} ) ( 1 - ɛ Γ S ) S$$

$$\frac{{dN}_{z}}{dt} = {N}_{sch} \frac{{υ}_{z}}{{τ}_{cap , z}} \frac{{W}_{sch 1}}{{W}_{qw}} + \frac{{N}_{z} - {N}_{z - 1}}{{τ}_{c}} - \frac{{N}_{z}}{{τ}_{e}} - \frac{{N}_{z}}{{τ}_{nqw}} - \frac{{N}_{z} - {N}_{z - 1}}{{τ}_{c}} - {v}_{g} g ( {N}_{z} ) ( 1 - ɛ Γ S ) S$$

$$\frac{{dN}_{M}}{dt} = {N}_{sch} \frac{{υ}_{M}}{{τ}_{cap , M}} \frac{{W}_{sch 1}}{{W}_{qw}} + \frac{{N}_{M} - {N}_{M - 1}}{{τ}_{c}} - \frac{{N}_{M}}{{τ}_{e}} - \frac{{N}_{M}}{{τ}_{nqw}} - {v}_{g} g ( {N}_{M} ) ( 1 - ɛ Γ S ) S$$

$$\frac{dS}{dt} = Γ {v}_{g} [ {\sum }_{z = 1}^{M} g ( {N}_{M} ) ] ( 1 - ɛ Γ S ) S - \frac{S}{{τ}_{p}} + \frac{β}{M} {\sum }_{z = 1}^{M} \frac{{N}_{z}}{{τ}_{n} ( {N}_{z} )}$$

S2: affect the distribution state of balanced photons of the laser by injection of the carriers matching the resonant cavity of the laser, and then cause the photons in the state to encounter external reflected light or laser light reflected by a laser window or an optical element to form a self-mixing interference effect, so as to improve the stability of the laser light output by the laser.

The parasitic parameter is a parasitic capacitance or a parasitic resistance; the DC bias circuit and the modulated signal generator are injected into the laser; the modulated signal, the parasitic capacitance, and the parasitic resistance constitute a resonance relationship which is embodied as a chirp effect in terms of optical output; resonant cavity laser output modes are increased, after a trace amount of returned light is applied to the laser, the influence of the self-mixing interference effect in multiple modes on the laser is less than that of equivalent self-mixing interference effect in a single mode or a few modes, and then the laser outputs stable laser beams.

As shown in FIG. 1, a laser system for reducing a self-mixing interference effect includes a laser 1 disposed along an optical axis (Z direction), and further includes a DC bias circuit 2 and a modulated signal generator 3. A resonant cavity is provided in the laser 1, and is configured to convert carriers for pumping into photons which are subjected to stimulated radiation to form stable laser output.

The laser 1 is electrically connected to the DC bias circuit 2 and the modulated signal generator 3; specifically, an output end of the DC bias circuit 2 is connected to an electrode of the laser, and an output end of the modulated signal generator 3 is connected to an electrode of the laser. The DC bias circuit 2 and the modulated signal generator 3 are equivalent to carrier sources, i.e., energy sources; the carriers are converted into photons by the resonant cavity, and the photons are subjected to stimulated radiation to produce laser light.

The DC bias circuit 2 is configured to drive the laser 1 and provide carriers for pumping to the laser 1. The DC bias circuit 2 matches electrical parameters of the laser. The DC bias circuit 2 may be a linear power supply or a stable switching power supply. In the present embodiment, the DC bias circuit 2 is preferably a linear power supply. The modulated signal generator 3 matches the modulated signal with a parasitic parameter of the laser to change the distribution state of the photons in the resonant cavity of the laser. In the present embodiment, the parasitic parameter is a parasitic capacitance or a parasitic resistance.

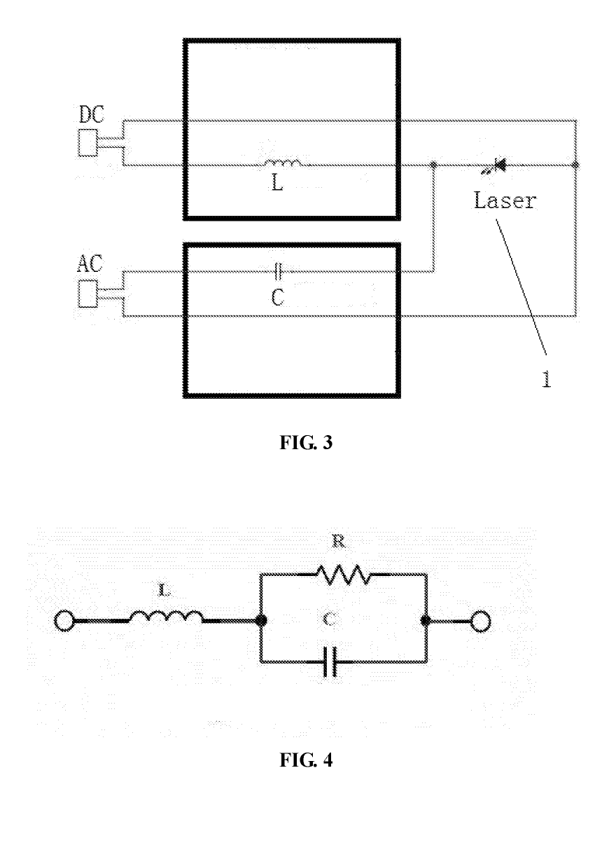

As shown in FIG. 3, the DC bias circuit 2 is a low-pass DC loop that includes a DC power supply. A positive pole of the DC power supply is connected to a cathode of the laser, and a negative pole of the DC power supply is connected to an anode of the laser by means of an inductor. In the present technical solution, the DC bias circuit 2 is a constant-current source with constant current. In the low-pass DC loop, an equivalent inductor mainly functions to block high-frequency components by means of a low-pass filter consisting of inductors. As shown in FIG. 3, the modulated signal generator 3 is a high-pass AC loop that includes an AC power supply. A positive pole of the AC power supply is connected to the cathode of the laser by means of a capacitor. The high-pass DC loop is mainly composed of a capacitor, an AC signal in-source impeder, and PCB traces; a high-frequency channel is formed to block DC components. In the present technical solution, the modulated signal generator 3 can generate a frequency within a radio-frequency range according to requirements. The signal passes through the capacitor, and the traces are coupled into the laser. Coupling here refers to AC coupling. Modulation is performed directly. The frequency of radio-frequency modulation ranges from 300 KHz to 300 GHz, and the waveform output by the radio-frequency modulation is approximate to a sinusoidal waveform.

As shown in FIG. 1, the laser system also includes an optical element 4 (DOE) spaced apart from the laser 1 and configured to guide the laser beams and/or shape the laser beams. The optical element 4 is a DOE. The material of the DOE 4 may be fused quartz, optical glass, or an optical resin material. In the present embodiment, the material of the DOE 4 is preferably the optical resin material. The reason why the optical resin material is selected is that the optical resin has the following advantages: the optical resin has good optical transparency; in a visible region, the light transmittance of the optical resin is similar to that of the glass; in an infrared region, the light transmittance of the optical resin is slightly higher than that of the glass; in an ultraviolet region, the light transmittance decreases as the wavelength decreases from 0.4 μm, and light having a wavelength of less than 0.3 μm is almost completely absorbed; the impact resistance is strong, the impact force of the optical resin is several times stronger than that of the glass, and the optical resin is non-breakable, safe, and durable. Certainly, in the working process, the optical glass can also be selected; the optical glass is preferably BK7 glass produced by SCHOTT Company in Germany, which is equivalent to domestic K9 glass; the specific parameters of the BK7 glass are as follows: the refractive index is 1.51680°, the acid resistance is 1°, and K hardness is 610.

The DOE 4 is made by a mold pressing or etching process. The DOE 4 is applicable for beam shaping of various lasers such as Nd:YAG, CO2, a femtosecond laser, and a semiconductor laser. The DOE 4 is mainly applied to laser beam shaping (such as laser processing, medical treatment, imaging systems, sensors, circular or square flat-topped beam shaping, and matrix, grid, linear and circular pattern shaping) and is used as a phase device in astronomy.

The DC bias circuit 2 and the modulated signal generator 3 are injected into the laser 1, the modulated signal output by the modulated signal generator 3 and the parasitic parameter of the laser constitute a resonance relationship; the resonant cavity laser output modes are increased, so as to affect the distribution state of balanced photons of the laser. The modulated signal needs to match the parameters of the laser, and during the matching process, the modulated signal can be effectively injected into the resonant cavity of the laser to affect the balance of carriers and photons in the resonant cavity of the laser to a certain extent.

After the DC bias circuit 2 and the modulated signal generator 3 are injected into the laser 1, the laser outputs laser beams 101, and the laser beams 101 pass through the DOE to output laser beams 102.

Embodiment 1: as shown in FIG. 1, the reflected light can be externally coupled into the laser 1, and can also be coupled into the laser 1 by the optical element, specifically: there are external reflected laser light 501, laser light 502 returned by the optical element, and laser light 503 returned by the laser in the transmission process of laser beams, the light returned in the process is inevitable in precision test structures, and essentially, 501, 502, and 503 are the same, and are all returned laser light. The main purpose of the present invention is to effectively reduce the influence of the returned light on the stability of the laser. The photons in the state then encounter the external reflected laser light 501, the laser light 502 returned by the optical element, and the laser light 503 returned by the laser to produce a self-mixing interference effect, so that the laser 1 outputs stable laser beams.

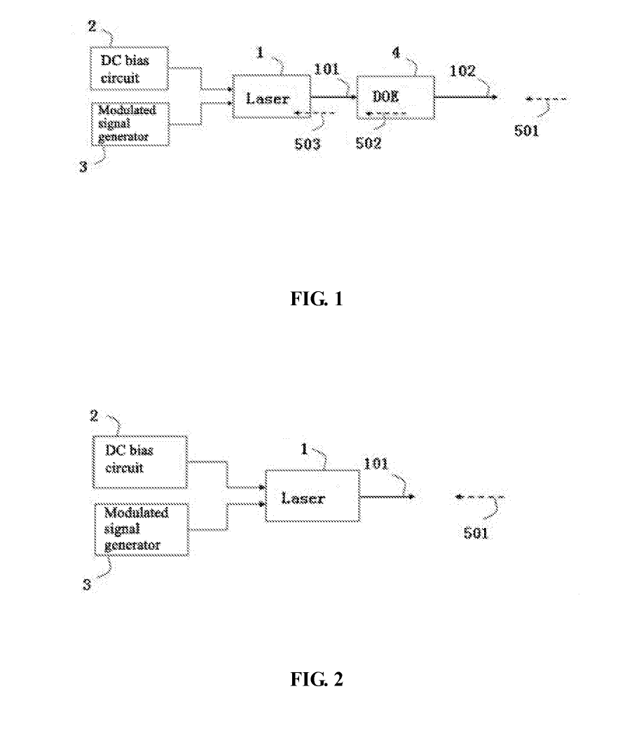

Embodiment 2: as shown in FIG. 2, the reflected light is externally coupled into the laser 1, specifically: there is external reflected laser light 501 in the transmission process of laser beams, the light returned in the process is inevitable in precision test structures, and essentially, 501 is the returned laser light. The main purpose of the present invention is to effectively reduce the influence of the returned light on the stability of the laser. The photons in the state then encounter the external reflected laser light 501 to produce a self-mixing interference effect, so that the laser 1 outputs stable laser beams.

In the present embodiment, the laser 1 is preferably a multi-quantum well laser, and the influence of key parameters such as photon density and carrier trapping, escaping and tunneling time on the frequency response characteristic of the multi-quantum well laser is obtained by using a multi-layer rate-equation model and a small-signal analysis method. By analyzing frequency response of the laser with parasitic electrical parameters of the laser and a parasitic circuit thereof, the parasitic circuit is obtained, and it is found that the parasitic capacitance in the parasitic circuit has a great influence on a modulation width. The parasitic capacitance matches a circuit for modulating signals, so that the injection efficiency of signals can be improved.

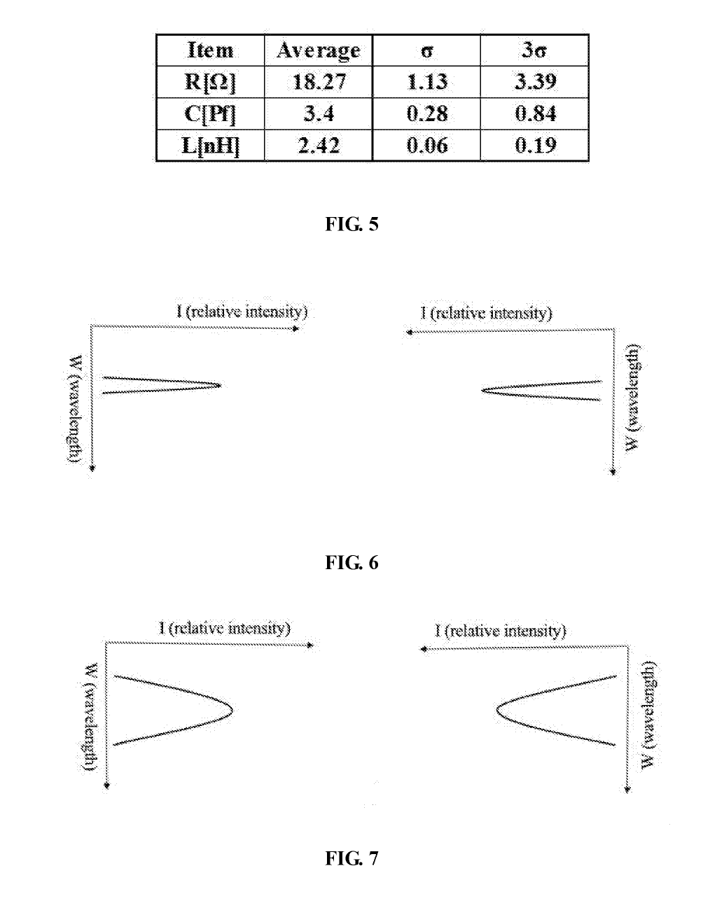

FIG. 4 is a schematic diagram of an AC equivalent circuit of a multi-quantum well laser. FIG. 5 is a parameter corresponding diagram of an equivalent capacitance and an equivalent resistance of a multi-quantum well laser. The relation equation of the carriers and the photons of the multi-quantum well laser is as follows:

$$\frac{{dN}_{sch}}{dt} = \frac{{η}_{i} J}{{qW}_{sch 1}} - {N}_{sch} {\sum }_{z = 1}^{M} \frac{{υ}_{2}}{{τ}_{cap , 1}} - \frac{{N}_{sch} ( 1 - {\sum }_{z = 1}^{M} {υ}_{2} )}{{τ}_{nsch}} - \frac{{N}_{M}}{{τ}_{c}} \frac{{W}_{qw}}{{W}_{sch 2}}$$

$$\frac{{dN}_{1}}{dt} = {N}_{sch} \frac{{υ}_{1}}{{τ}_{cap , 1}} \frac{{W}_{sch 1}}{{W}_{qw}} - \frac{{N}_{1}}{{τ}_{c}} - \frac{{N}_{1}}{{τ}_{nqw}} - \frac{{N}_{1} - {N}_{2}}{{τ}_{c}} - {v}_{g} g ( {N}_{z} ) ( 1 - ɛ Γ S ) S$$

$$\frac{{dN}_{z}}{dt} = {N}_{sch} \frac{{υ}_{z}}{{τ}_{cap , z}} \frac{{W}_{sch 1}}{{W}_{qw}} + \frac{{N}_{z} - {N}_{z - 1}}{{τ}_{c}} - \frac{{N}_{z}}{{τ}_{e}} - \frac{{N}_{z}}{{τ}_{nqw}} - \frac{{N}_{z} - {N}_{z - 1}}{{τ}_{c}} - {v}_{g} g ( {N}_{z} ) ( 1 - ɛ Γ S ) S$$

$$\frac{{dN}_{M}}{dt} = {N}_{sch} \frac{{υ}_{M}}{{τ}_{cap , M}} \frac{{W}_{sch 1}}{{W}_{qw}} + \frac{{N}_{M} - {N}_{M - 1}}{{τ}_{c}} - \frac{{N}_{M}}{{τ}_{e}} - \frac{{N}_{M}}{{τ}_{nqw}} - {v}_{g} g ( {N}_{M} ) ( 1 - ɛ Γ S ) S$$

$$\frac{dS}{dt} = Γ {v}_{g} [ {\sum }_{z = 1}^{M} g ( {N}_{M} ) ] ( 1 - ɛ Γ S ) S - \frac{S}{{τ}_{p}} + \frac{β}{M} {\sum }_{z = 1}^{M} \frac{{N}_{z}}{{τ}_{n} ( {N}_{z} )}$$

It can be known from the equation above that a differential gain increases with the increase of a light limiting factor, and moreover, the photons of the multi-quantum well laser would have a greater relaxation oscillation efficiency; if the signal modulation parameter is related to the relaxation oscillation efficiency of the multi-quantum well laser, the distribution of modes in the resonant cavity of the laser would be influenced in the process, and the resonant states of light of multiple longitudinal modes can be stably produced. In the process, because the external reflected light or the laser light reflected by the laser window or the optical element is coupled into the resonant cavity of the laser, the self-mixing interference effect would be weakened due to the increase of the longitudinal modes of the laser, or the interference capability of the comprehensive capacity to the original mode distribution of the resonant cavity is weakened, so as to further spatially reduce the influence of the self-mixing interference effect on the stability of the laser.

The modulated signal generator may be a digital signal generator or an analog signal generator. In the present embodiment, the modulated signal generator is preferably a digital signal generator which modulates digital signals matching parameters of the laser. Superposition of the modulated signals would average the influences of the self-mixing interference effect generated by the external reflected laser light or the laser light reflected by the laser window or the DOE in the unit detection time. Due to the function of the modulated signals, delay of conversion between the carriers and the photons and the chirp effect of optical modulation further temporally reduce the influence of the self-mixing interference effect on the stability of the laser.

FIG. 7 is a distribution diagram of the relative light intensity of a laser for spatially reducing a self-mixing interference effect. FIG. 6 is a distribution diagram of the relative light intensity without using the present invention. FIG. 7 is a distribution diagram of the relative light intensity using the present invention. It can be seen from FIG. 7 that: after the DC bias circuit 2 and the modulated signal generator 3 are injected into the laser 1, the original state of the resonant cavity of the laser is damaged, the conversion relation of the carriers and the photons in the resonant cavity is changed, and the number of longitudinal modes of laser output in the resonant cavity is increased, which is embodied as a spectral width of an output spectrum; in this way, the overall influence of self-mixing the returned light of similar energy into the resonant cavity spatially on the photons in an original stimulated radiation mode is greatly improved as compared with the example without using the present invention in FIG. 6.

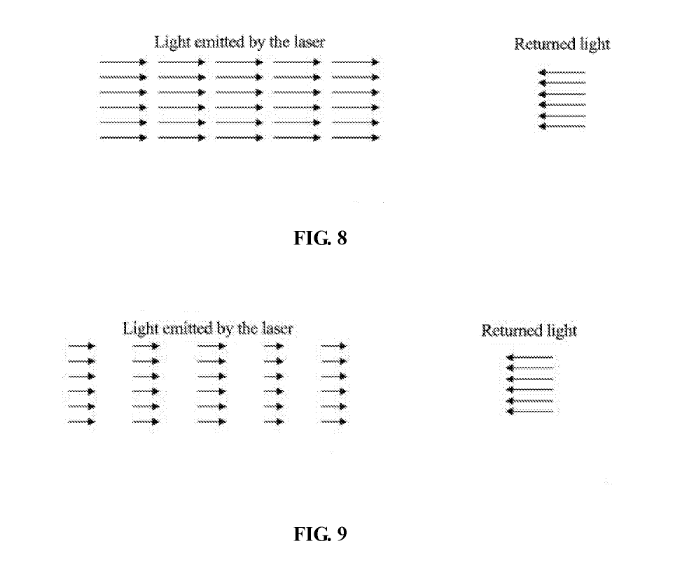

FIG. 9 is a schematic structural diagram of a laser for spatially reducing a self-mixing interference effect. FIG. 8 is an example without using the present invention. FIG. 9 is an example using the present invention. It can be seen from FIG. 9 that: after the DC bias circuit 2 and the modulated signal generator 3 are injected into the laser, the original state of the resonant cavity of the laser is damaged, the conversion relation of the carriers and the photons in the resonant cavity is changed, and therefore, the overall influence of delay of conversion between the carriers and the photons, the chirp effect caused by modulation, and self-mixing of the returned light of similar time duration into the resonant cavity in time dimension on the photons in an original stimulated radiation mode is greatly improved as compared with the example without using the present invention in FIG. 7.

The self-mixing interference effect has bad influence on laser production, would directly influence the stability of light beams output by the laser 1, and even would seriously influence the service life of the laser 1. The system spatially and temporally reduces power fluctuation of the laser within a short period of time caused by the self-mixing interference effect, and ensures the stability of the whole laser system.

The laser system is simple and feasible in use, can effectively reduce the decrease in stability of the laser caused by the self-mixing interference effect by changing the balance in the resonant cavity according to the relationships between the photons and the carriers of the resonant cavity, has the advantages of a simple structure, less energy loss in use, low cost, easy assembly and adjustment, and stable performance, and is applicable to efficient and stable laser systems. Moreover, redundancy and indeterminacy of the laser system are avoided in use.

It would be obvious to a person of ordinary skill in the art that the present invention is not limited to the details of the above-mentioned exemplary embodiments, and moreover, the present invention can be achieved in other specific forms without departing from the spirit and essential features of the present invention. Therefore, the embodiments shall be considered in all respects as exemplary and non-restrictive. The scope of the present invention is defined by the appended claims rather than the above-mentioned description, and all variations falling within the meaning and scope of equivalent elements of the claims are therefore intended to be embraced therein. Any reference numeral in the claims shall not be considered to limit the involved claims.

In addition, it should be understood that although the specification is described according to embodiments, not every embodiment includes only one separate technical solution. The specification is described only for clarity. A person of ordinary skill in the art shall regard the specification as a whole, and the technical solutions in the embodiments can also be appropriately combined to form other embodiments that can be understood by a person of ordinary skill in the art.

1. A method for reducing a self-mixing interference effect of a laser system, comprising the following steps:
S1: connecting a DC bias circuit (2) and a modulated signal generator (3) to electrodes of a laser (1), respectively, wherein the DC bias circuit (2) is configured to drive the laser (1) and provide carriers for pumping to the laser (1); a resonant cavity is provided in the laser (1), and is configured to convert the carriers for pumping into photons which are subjected to stimulated radiation to form stable laser output; the DC bias circuit (2) and the modulated signal generator (3) are injected into the laser; the modulated signal generator (3) outputs a modulated signal; and the modulated signal matches a parasitic parameter of the laser so as to change the distribution state of the photons in the resonant cavity of the laser;
the relation equation of the carriers and the photons of the laser is as follows:
$$\frac{{dN}_{sch}}{dt} = \frac{{η}_{i} J}{{qW}_{sch 1}} - {N}_{sch} {\sum }_{z = 1}^{M} \frac{{υ}_{2}}{{τ}_{cap , 1}} - \frac{{N}_{sch} ( 1 - {\sum }_{z = 1}^{M} {υ}_{2} )}{{τ}_{nsch}} - \frac{{N}_{M}}{{τ}_{c}} \frac{{W}_{qw}}{{W}_{sch 2}}$$
$$\frac{{dN}_{1}}{dt} = {N}_{sch} \frac{{υ}_{1}}{{τ}_{cap , 1}} \frac{{W}_{sch 1}}{{W}_{qw}} - \frac{{N}_{1}}{{τ}_{c}} - \frac{{N}_{1}}{{τ}_{nqw}} - \frac{{N}_{1} - {N}_{2}}{{τ}_{c}} - {v}_{g} g ( {N}_{z} ) ( 1 - ɛ Γ S ) S$$
$$\frac{{dN}_{z}}{dt} = {N}_{sch} \frac{{υ}_{z}}{{τ}_{cap , z}} \frac{{W}_{sch 1}}{{W}_{qw}} + \frac{{N}_{z} - {N}_{z - 1}}{{τ}_{c}} - \frac{{N}_{z}}{{τ}_{e}} - \frac{{N}_{z}}{{τ}_{nqw}} - \frac{{N}_{z} - {N}_{z - 1}}{{τ}_{c}} - {v}_{g} g ( {N}_{z} ) ( 1 - ɛ Γ S ) S$$
$$\frac{{dN}_{M}}{dt} = {N}_{sch} \frac{{υ}_{M}}{{τ}_{cap , M}} \frac{{W}_{sch 1}}{{W}_{qw}} + \frac{{N}_{M} - {N}_{M - 1}}{{τ}_{c}} - \frac{{N}_{M}}{{τ}_{e}} - \frac{{N}_{M}}{{τ}_{nqw}} - {v}_{g} g ( {N}_{M} ) ( 1 - ɛ Γ S ) S$$
$$\frac{dS}{dt} = Γ {v}_{g} [ {\sum }_{z = 1}^{M} g ( {N}_{M} ) ] ( 1 - ɛ Γ S ) S - \frac{S}{{τ}_{p}} + \frac{β}{M} {\sum }_{z = 1}^{M} \frac{{N}_{z}}{{τ}_{n} ( {N}_{z} )}$$
S2: affecting the distribution state of balanced photons of the laser by injection of the carriers matching the resonant cavity of the laser, and then causing the photons in the state to encounter external reflected light or laser light reflected by a laser window or an optical element to form a self-mixing interference effect, so as to improve the stability of the laser light output by the laser.

2. The method for reducing a self-mixing interference effect of a laser system according to claim 1, wherein the parasitic parameter is a parasitic capacitance or a parasitic resistance; the DC bias circuit (2) and the modulated signal generator (3) are injected into the laser (1); the modulated signal, the parasitic capacitance, and the parasitic resistance constitute a resonance relationship which is embodied as a chirp effect in terms of optical output; resonant cavity laser output modes are increased, after a trace amount of returned light is applied to the laser, the influence of the self-mixing interference effect in multiple modes on the laser is less than that of equivalent self-mixing interference effect in a single mode or a few modes, and then the laser (1) outputs stable laser beams.

3. The method for reducing a self-mixing interference effect of a laser system according to claim 1, wherein the laser (1) is disposed along an optical axis (Z direction), the DC bias circuit (2) and the modulated signal generator (3) are spaced apart from the laser (1), and the laser (1) is electrically connected to the DC bias circuit (2) and the modulated signal generator (3).

4. The method for reducing a self-mixing interference effect of a laser system according to claim 1, wherein an optical element (4) configured to guide the light beams and/or shape the laser beams is disposed behind the laser (1) at an interval.

5. The method for reducing a self-mixing interference effect of a laser system according to claim 1, wherein the modulated signal generator (3) may be a digital signal generator or an analog signal generator.

6. The method for reducing a self-mixing interference effect of a laser system according to claim 4, wherein the optical element (4) is a diffractive optical element (DOE).

7. The method for reducing a self-mixing interference effect of a laser system according to claim 3, wherein the modulated signal generator (3) may be a digital signal generator or an analog signal generator.
